(19) United States
(12) Patent Application Publication
(10) Pub. No.: US 2026/0090182 A1
(43) Pub. Date: Mar. 26, 2026

(54) PHOTOELECTRIC CONVERSION DEVICE AND METHOD FOR MANUFACTURING THE SAME

(71) Applicants: KABUSHIKI KAISHA TOSHIBA, Kawasaki-shi (JP); Toshiba Energy Systems & Solutions Corporation, Kawasaki-shi (JP)

(72) Inventors: Nobuaki Makino, Fujisawa Kanagawa (JP); Masakuni Ikagawa, Ebina Kanagawa (JP)

(21) Appl. No.: 19/316,647

(22) Filed: Sep. 2, 2025

(30) Foreign Application Priority Data
Sep. 20, 2024 (JP) 2024-163637

(51) Int. Cl. H10K 30/88; H10K 30/40; H10K 71/20

(52) U.S. Cl. CPC H10K 30/88; H10K 30/40; H10K 71/20

(57) ABSTRACT

In general, according to one embodiment, a photoelectric conversion device includes a glass substrate having a thickness of 250 μm or less and having a first surface and a second surface located on a back side of the first surface; a photoelectric conversion element provided on the first surface of the glass substrate; and a silicone resin-containing layer provided on the second surface of the glass substrate.

### CROSS-REFERENCE TO RELATED APPLICATION

This application is based upon and claims the benefit of priority from Japanese Patent Application No. 2024-163637, filed Sep. 20, 2024, the entire contents of which are incorporated herein by reference.

### FIELD

Embodiments described herein relate generally to a photoelectric conversion device and a method for manufacturing the same.

### BACKGROUND

A photoelectric conversion device such as a perovskite type solar cell needs a measure to prevent transmission of water vapor and O₂ in order to prevent deterioration due to water vapor and O₂. A glass substrate is a material having a high barrier property against water vapor or the like. Therefore, the glass substrate enables a sealing structure having a high barrier property. On the other hand, a solar cell having a sealing structure using a glass substrate has a problem in impact resistance in outdoor use or the like. When the glass substrate is thickened in order to enhance impact resistance, it is difficult to impart flexibility in shape to the solar cell.

### BRIEF DESCRIPTION OF DRAWINGS

FIG. 1 is a schematic cross-sectional view illustrating a first example of a photoelectric conversion device according to an embodiment.

FIG. 2 is a schematic cross-sectional view illustrating an example of a photoelectric conversion element of the photoelectric conversion device illustrated in FIG. 1.

FIG. 3 is a schematic cross-sectional view illustrating a second example of the photoelectric conversion device according to the embodiment.

FIG. 4 is a schematic cross-sectional view illustrating a third example of the photoelectric conversion device according to the embodiment.

FIG. 5 is a schematic cross-sectional view illustrating a fourth example of the photoelectric conversion device according to the embodiment.

FIG. 6 is a schematic cross-sectional view illustrating a fifth example of the photoelectric conversion device according to the embodiment.

FIG. 7 is a schematic cross-sectional view illustrating a sixth example of the photoelectric conversion device according to the embodiment.

FIG. 8 is a schematic cross-sectional view illustrating one step of a method I for manufacturing the photoelectric conversion device of the first example.

FIG. 9 is a schematic cross-sectional view illustrating one step of the method I for manufacturing the photoelectric conversion device of the first example.

FIG. 10 is a schematic cross-sectional view illustrating one step of the method I for manufacturing the photoelectric conversion device of the first example.

FIG. 11 is a schematic cross-sectional view illustrating one step of the method I for manufacturing the photoelectric conversion device of the first example.

FIG. 12 is a schematic cross-sectional view illustrating one step of a method II for manufacturing the photoelectric conversion device of the first example.

FIG. 13 is a schematic cross-sectional view of a laminate illustrated in FIG. 12.

FIG. 14 is a schematic cross-sectional view illustrating one step of the method II for manufacturing the photoelectric conversion device of the first example.

FIG. 15 is a schematic cross-sectional view illustrating one step of the method II for manufacturing the photoelectric conversion device of the first example.

FIG. 16 is a schematic cross-sectional view illustrating one step of the method II for manufacturing the photoelectric conversion device of the first example.

FIG. 17 is a schematic cross-sectional view illustrating one step of a method III for manufacturing the photoelectric conversion device of the second example.

FIG. 18 is a schematic cross-sectional view illustrating one step of a method V for manufacturing the photoelectric conversion device of the fourth example.

FIG. 19 is a schematic cross-sectional view illustrating one step of the method V for manufacturing the photoelectric conversion device of the fourth example.

FIG. 20 is a schematic cross-sectional view illustrating one step of the method V for manufacturing the photoelectric conversion device of the fourth example.

FIG. 21 is a schematic cross-sectional view illustrating one step of a method VI for manufacturing the photoelectric conversion device of the fifth example.

FIG. 22 is a schematic cross-sectional view illustrating one step of the method VI for manufacturing the photoelectric conversion device of the fifth example.

FIG. 23 is a schematic cross-sectional view illustrating one step of a method VII for manufacturing the photoelectric conversion device of the sixth example.

FIG. 24 is a schematic cross-sectional view illustrating an iron ball drop test in Examples.

### DETAILED DESCRIPTION

In general, according to one embodiment, a photoelectric conversion device is provided. The photoelectric conversion device includes:
a glass substrate having a thickness of 250 μm or less and having a first surface and a second surface located on a back side of the first surface;
a photoelectric conversion element provided on the first surface of the glass substrate; and
a silicone resin-containing layer provided on the second surface of the glass substrate.

According to the embodiment, a method for manufacturing a photoelectric conversion device is provided. The method includes:
forming a photoelectric conversion element on a first surface of a glass substrate;
chemically polishing a second surface located on a back side of the first surface of the glass substrate to adjust a thickness of the glass substrate to 250 μm or less; and
forming a silicone resin-containing layer on the second surface of the glass substrate.

According to another embodiment, a method for manufacturing a photoelectric conversion device is provided. The method includes:
stacking a first structure portion including a first glass substrate having a first surface and a second surface and a first photoelectric conversion element provided on the first surface of the first glass substrate, and a second structure portion including a second glass substrate having a first surface and a second surface and a second photoelectric conversion element provided on the first surface of the second glass substrate, and obtaining a laminate having a structure in which the first photoelectric conversion element and the second photoelectric conversion element are located between the first surface of the first glass substrate and the first surface of the second glass substrate;
chemically polishing the second surface of the first glass substrate and the second surface of the second glass substrate in the laminate to adjust thicknesses of the first glass substrate and the second glass substrate to 250 μm or less;
separating, from the laminate, the first structure portion and the second structure portion; and
forming a silicone resin-containing layer on the second surface of the first glass substrate of the first structure portion and the second surface of the second glass substrate of the second structure portion.

According to another embodiment, a method for manufacturing a photoelectric conversion device is provided. The method includes:
stacking a first glass substrate provided with a first photoelectric conversion element on a first surface and a second glass substrate provided with a second photoelectric conversion element on a first surface into a structure in which the first photoelectric conversion element and the second photoelectric conversion element are located between the first surface of the first glass substrate and the first surface of the second glass substrate;
chemically polishing a second surface located on a back side of the first surface of the first glass substrate and a second surface located on a back side of the first surface of the second glass substrate in the obtained laminate to adjust thicknesses of the first glass substrate and the second glass substrate to 250 μm or less; and
forming a silicone resin-containing layer on the second surface of the first glass substrate and the second surface of the second glass substrate.

According to another embodiment, a method for manufacturing a photoelectric conversion device is provided. The method includes:
stacking a first glass substrate provided with a first photoelectric conversion element on a first surface and a second glass substrate having a first surface into a structure in which the first photoelectric conversion element is located between the first surface of the first glass substrate and the first surface of the second glass substrate;
chemically polishing a second surface located on a back side of the first surface of the first glass substrate and a second surface located on a back side of the first surface of the second glass substrate in the obtained laminate to adjust thicknesses of the first glass substrate and the second glass substrate to 250 μm or less; and
forming a silicone resin-containing layer on the second surface of the first glass substrate and the second surface of the second glass substrate.

### First Embodiment

According to the first embodiment, a photoelectric conversion device is provided. The photoelectric conversion device may be, for example, a solar cell, organic electroluminescence (organic EL), or the like. Examples of the solar cell include a perovskite type solar cell.

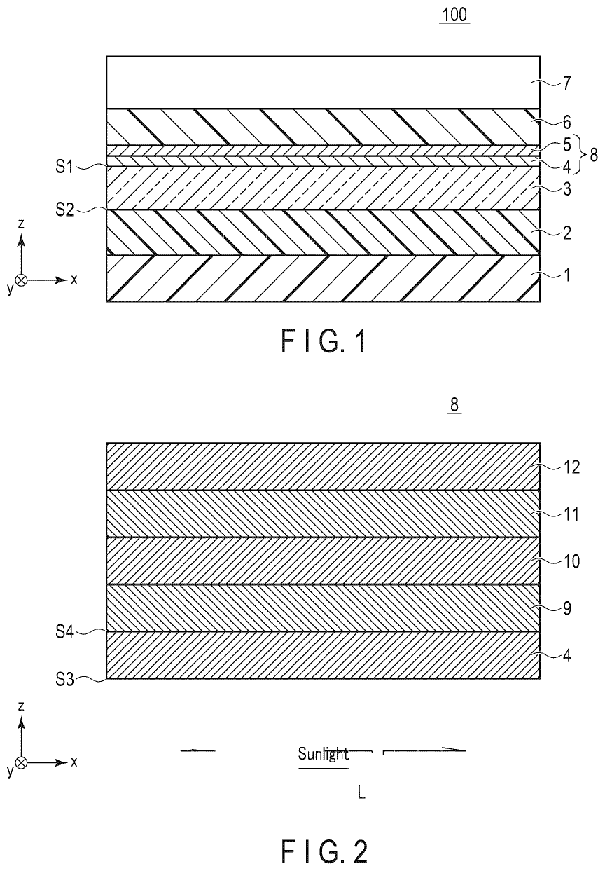

An example in which the photoelectric conversion device of the embodiment is applied to a solar cell will be described with reference to FIGS. 1 to 7. In each figure, it is assumed that a stacking direction of the photoelectric conversion device and a thickness direction of the glass substrate are parallel to the z-axis direction. It is assumed that a plane direction of the photoelectric conversion device is parallel to the xy plane. The x-axis direction, the y-axis direction, and the z-axis direction intersect each other substantially perpendicularly. In each figure, members commonly present in a plurality of figures are denoted by the same reference numerals, and description thereof is omitted.

### First Example

FIG. 1 illustrates a first example of the photoelectric conversion device according to the embodiment. A solar cell 100 of the first example includes a layer 1 having shielding performance against ultraviolet rays, a silicone resin-containing layer 2, a glass substrate 3, a transparent electrode 4, an element portion 5, an adhesive layer 6, and a back sheet 7. The members are stacked in the z-axis direction.

The glass substrate 3 has a thickness of 250 μm or less. A lower limit value of the thickness of the glass substrate 3 is desirably 30 μm. The glass substrate 3 has a first surface S1 and a second surface S2 located on a back side of the first surface S1. Each of the first surface S1 and the second surface S2 is a surface parallel to the xy plane. The glass substrate 3 may or may not be capable of shielding ultraviolet rays. The shielding performance against ultraviolet rays may not transmit ultraviolet rays, may absorb ultraviolet rays, or may scatter ultraviolet rays. Desirably, the glass substrate 3 can shield ultraviolet rays having a wavelength of 350 nm or less.

The transparent electrode 4 is provided on the first surface S1 of the glass substrate 3. The element portion is provided on the transparent electrode 4. The transparent electrode 4 and the element portion 5 constitute a solar cell element 8 which is a photoelectric conversion element. Hereinafter, the solar cell element 8 will be described with reference to FIG. 2. The solar cell element 8 includes the transparent electrode 4 as a first electrode, a hole transport layer 9, a photoelectric conversion layer 10, an electron transport layer 11, and a cathode 12 as a second electrode. In each of the transparent electrode 4, the hole transport layer 9, the photoelectric conversion layer 10, the electron transport layer 11, and the cathode 12, two surfaces intersecting with the thickness direction (z-axis direction) are principal surfaces (main surfaces). Each surface is parallel to the xy plane. One surface S3 of the transparent electrode 4 parallel to the xy plane is stacked on the first surface S1 of the glass substrate 3. The hole transport layer 9, the photoelectric conversion layer 10, the electron transport layer 11, and the cathode 12 are provided in this order on the other surface S4 of the transparent electrode 4 parallel to the xy plane. Light such as sunlight and illumination light is applied, for example, from a direction indicated by arrow L to the transparent electrode 4 side through the glass substrate 3 or the like.

Examples of the transparent electrode 4 as the first electrode include a film made of a material having light transmittance and electrical conductivity, such as indium tin oxide (ITO), zinc oxide (ZnO), tin dioxide (SnO₂), or fluorine-doped tin oxide (FTO).

The hole transport layer 9 has, for example, a function of blocking electrons generated in the photoelectric conversion layer 10 and selectively and efficiently transporting holes to the cathode 12.

Examples of the photoelectric conversion layer 10 include a perovskite layer. Examples of a perovskite type compound include methylammonium lead iodide (CH₃NH₃PbI₃).

The electron transport layer 11 has, for example, a function of blocking holes generated in the photoelectric conversion layer 10 and selectively and efficiently transporting electrons to the transparent electrode 4.

The cathode 12 as the second electrode is made of a material having electrical conductivity and, in some cases, light transmittance. Examples of the cathode 12 include a layer containing Ti and/or Al.

The back sheet 7 is fixed to one surface of the cathode 12 parallel to the xy plane by the adhesive layer 6. Examples of the back sheet 7 include a sheet obtained by coating a polyethylene terephthalate (PET) film with aluminum.

A thickness of the solar cell element 8 is set to a desired value according to the type of the solar cell, the element area, and the like. An example of the thickness can be about 500 nm.

One surface of the silicone resin-containing layer 2 parallel to the xy plane is stacked on the second surface S2 of the glass substrate 3. The layer 1 having shielding performance against ultraviolet rays (hereinafter, referred to as UV shielding layer) is stacked on the other surface of the silicone resin-containing layer 2 parallel to the xy plane. A thickness of the silicone resin-containing layer 2 is desirably 300 μm or less. The silicone resin-containing layer 2 may or may not have shielding performance against ultraviolet rays. When at least one of the silicone resin-containing layer 2 or the glass substrate 3 has shielding performance against ultraviolet rays, the UV shielding layer 1 can be omitted. The silicone resin-containing layer 2 desirably contains a silicone resin as a main component. Here, the main component is a component having the highest content in the silicone resin-containing layer 2.

When one or more members of the UV shielding layer 1, the silicone resin-containing layer 2, and the glass substrate 3 can shield ultraviolet rays, the wavelength of the ultraviolet ray is desirably 350 nm or less. More desirably, ultraviolet rays having a wavelength of 350 nm or less can be shielded, and light having a wavelength of 400 nm or more can be transmitted. Examples of materials capable of shielding ultraviolet rays having a wavelength of 350 nm or less and transmitting light having a wavelength of 400 nm or more include TiO₂ and WO₃.

When the solar cell 100 having the above structure is irradiated with light, for example, on the UV shielding layer 1 side, and the photoelectric conversion layer 10 absorbs the irradiated light, electrons and holes paired therewith are generated. Among the generated electrons and holes, for example, the electrons are collected by the cathode 12 via the electron transport layer 11. The holes are collected by the transparent electrode 4 via the hole transport layer 9. In this way, a photoelectric conversion reaction occurs.

By adjusting a thickness of the glass substrate 3 to 250 μm or less, a weight of the solar cell 100 can be reduced. In addition, since the shape of the solar cell 100 can be made flexible, the solar cell 100 can be easily deformed into a desired shape such as being bent. The silicone resin has a weak intermolecular force, and thus has high elasticity, and easily absorbs impact. The silicone resin-containing layer 2 can protect the glass substrate 3 from impact while securing weight reduction and flexibility of the solar cell. Specifically, it is possible to realize impact resistance that can withstand a hailfall test in accordance with JIS C 8917:2005 Environmental and endurance test methods for crystalline solar PV modules. As a result, damage to the glass substrate 3 can be suppressed even when the solar cell 100 is used outdoors, so that the gas barrier property of the glass substrate 3 against water vapor and O₂ can be maintained for a long period of time.

### Second Example

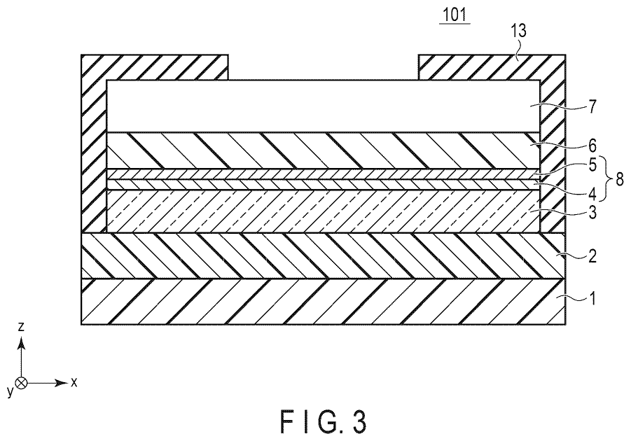

A second example of the solar cell of the embodiment will be described with reference to FIG. 3. A solar cell 101 illustrated in FIG. 3 has the same configuration as the solar cell 100 except for including a first seal member 13. The first seal member 13 covers end portions (four side surfaces) of respective members, i.e., a glass substrate 3, a transparent electrode 4, an element portion 5, an adhesive layer 6, and a back sheet 7. In addition, the first seal member 13 covers an edge portion of a surface of the back sheet 7 parallel to the xy plane. An end portion of the first seal member 13 is fixed to the silicone resin-containing layer 2. As the first seal member 13, for example, an insulating tape can be used. The first seal member 13 can protect the glass substrate 3 from impact. Therefore, the impact resistance of the solar cell 101 can be further improved, and the reliability of the solar cell 101 can be further improved.

### Third Example

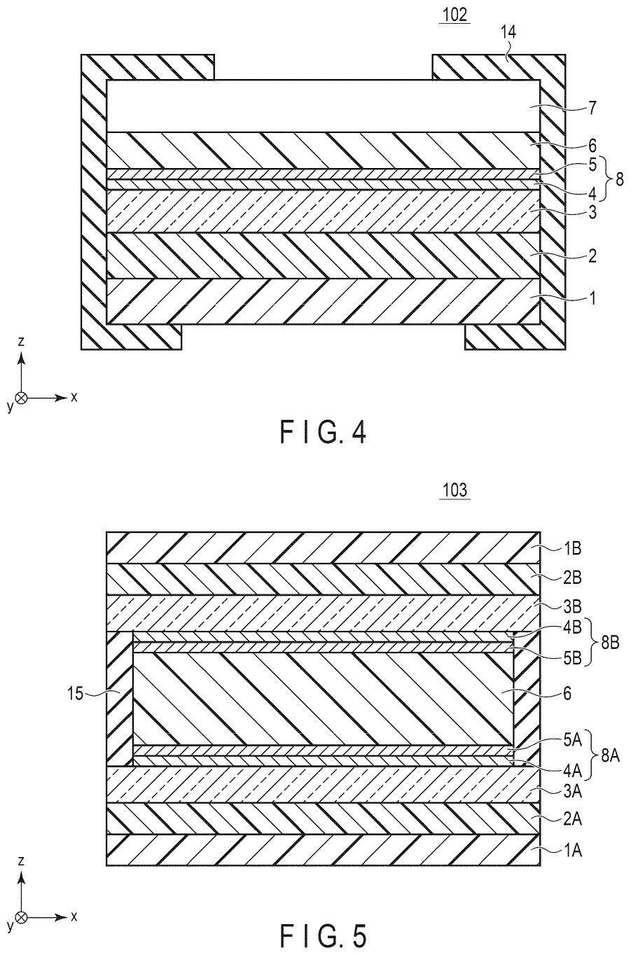

A third example of the solar cell of the embodiment will be described with reference to FIG. 4. A solar cell 102 illustrated in FIG. 4 has the same configuration as the solar cell 100 except for including a second seal member 14. The second seal member 14 covers end portions (four side surfaces) of respective members, i.e., a UV shielding layer 1, a silicone resin-containing layer 2, a glass substrate 3, a transparent electrode 4, an element portion 5, an adhesive layer 6, and a back sheet 7. In addition, the second seal member 14 covers the edge portion of the surface of the back sheet 7 parallel to the xy plane and an edge portion of a surface of the UV shielding layer 1 parallel to the xy plane. As the second seal member 14, for example, an insulating tape can be used. The second seal member 14 can protect the glass substrate 3 from impact. Therefore, the impact resistance of the solar cell 102 can be further improved, and the reliability of the solar cell 102 can be further improved.

### Fourth Example

A fourth example of the solar cell of the embodiment will be described with reference to FIG. 5. A solar cell 103 illustrated in FIG. 5 includes first and second solar cell elements 8A and 8B and first and second glass substrates 3A and 3B. An element portion 5A of the first solar cell element 8A and an element portion 5B of the second solar cell element 8B are bonded to each other with an adhesive layer 6 interposed therebetween. The first glass substrate 3A, a first silicone resin-containing layer 2A, and a first UV shielding layer 1A are stacked in this order on a first transparent electrode 4A of the first solar cell element 8A. The second glass substrate 3B, a second silicone resin-containing layer 2B, and a second UV shielding layer 1B are stacked in this order on a second transparent electrode 4B of the second solar cell element 8B. A third seal member 15 covers end portions (four side surfaces) of the first and second solar cell elements 8A and 8B bonded to each other by the adhesive layer 6. The third seal member 15 can protect the solar cell elements 8. The third seal member 15 is formed of, for example, an insulating resin such as an epoxy resin. According to the solar cell 103 described above, it is possible to generate power by taking in light from both outermost layers of a laminate. Therefore, the power generation efficiency of the solar cell at a constant volume can be increased. Although FIG. 5 illustrates a case of one adhesive layer 6, the adhesive layer 6 is not limited thereto, and two or more adhesive layers 6, for example, may be provided.

### Fifth Example

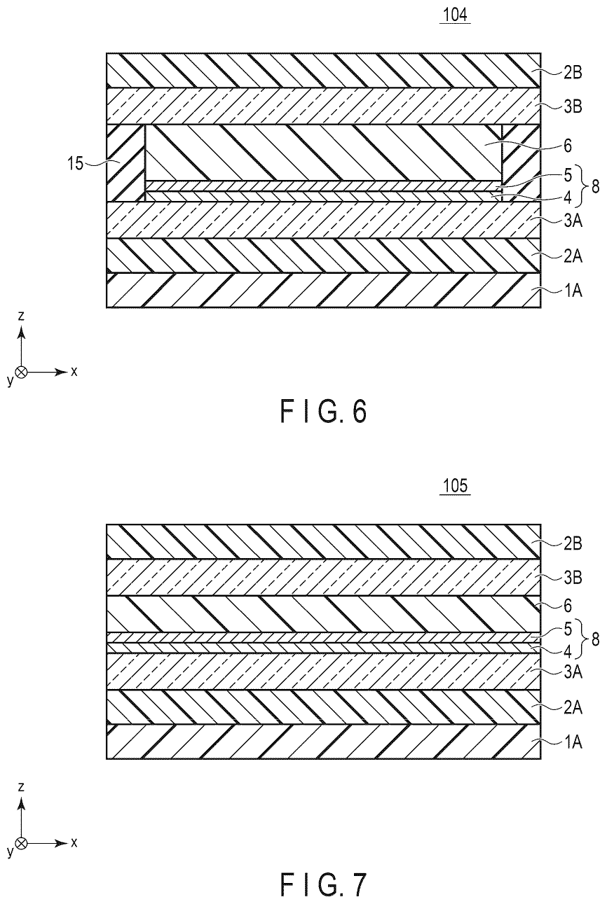

A fifth example of the solar cell of the embodiment will be described with reference to FIG. 6. A solar cell 104 illustrated in FIG. 6 includes a solar cell element 8 and first and second glass substrates 3A and 3B. The first glass substrate 3A, a first silicone resin-containing layer 2A, and a first UV shielding layer 1A are stacked in this order on a transparent electrode 4 of the solar cell element 8. The second glass substrate 3B is fixed to an element portion 5 of the solar cell element 8 by an adhesive layer 6. A second silicone resin-containing layer 2B is stacked on the second glass substrate 3B. The second glass substrate 3B is not provided with a solar cell element. Therefore, it is not necessary to provide a UV shielding layer on the second silicone resin-containing layer 2B, but a UV shielding layer may be provided.

A third seal member 15 covers end portions (four side surfaces) of the solar cell element 8 and the adhesive layer 6. Both end portions of the third seal member 15 in the z-axis direction are fixed to the first and second glass substrates 3A and 3B. The third seal member 15 can protect the solar cell elements 8. The third seal member 15 is formed of, for example, an insulating resin such as an epoxy resin. The solar cell 104 described above has an excellent barrier function against gases such as water vapor and oxygen, since the solar cell element 8 is located between the first glass substrate 3A and the second glass substrate 3B. Therefore, it is possible to suppress deterioration of the solar cell element 8 due to water vapor and oxygen.

### Sixth Example

A sixth example of the solar cell of the embodiment will be described with reference to FIG. 7. A solar cell 105 illustrated in FIG. 7 has the same structure as the solar cell 104 of the fifth example except that the third seal member 15 is not used. The solar cell 105 has an excellent barrier function against gases such as water vapor and oxygen, since a solar cell element 8 is located between a first glass substrate 3A and a second glass substrate 3B. Therefore, it is possible to suppress deterioration of the solar cell element 8 due to water vapor and oxygen.

The solar cells of the embodiment exemplified in first to sixth examples include a glass substrate having a thickness of 250 μm or less, a photoelectric conversion element provided on a first surface of the glass substrate, and a silicone resin-containing layer provided on a second surface of the glass substrate. According to the solar cells of the embodiment, it is possible to realize excellent impact resistance while reducing the weight and improving the flexibility. The solar cells of the embodiment also ensure a barrier function against gases such as water vapor and oxygen. Further, as illustrated in Examples, the solar cells of the embodiment can realize impact resistance that can withstand a hailfall test in accordance with JIS C 8917:2005 Environmental and endurance test methods for crystalline solar PV modules. As a result, damage to the glass substrate can be suppressed even when the solar cells are used outdoors, so that the gas barrier property of the glass substrate against water vapor, oxygen, and the like can be maintained for a long period of time.

In the above examples, the first electrode (transparent electrode 4) is an anode and the second electrode is a cathode 12, but the arrangement of these electrodes may be reversed. That is, the first electrode (transparent electrode 4) may be a cathode and the second electrode may be an anode. In this case, the arrangement of the hole transport layer 9 and the electron transport layer 11 is also switched.

### Second Embodiment

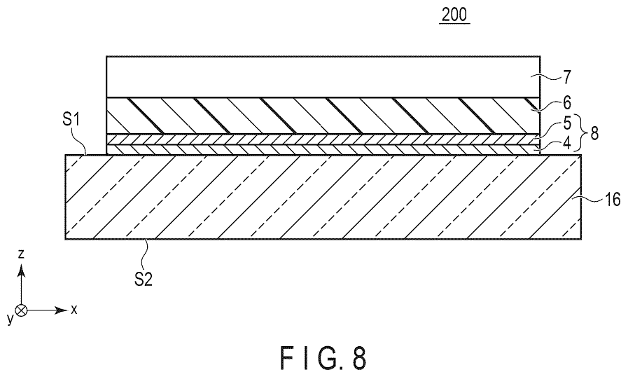

According to a second embodiment, a method for manufacturing the photoelectric conversion device of the first embodiment is provided. An example in which the method of the second embodiment is applied to a method for manufacturing a solar cell will be described with reference to FIGS. 8 to 24. In each figure, it is assumed that a stacking direction of the photoelectric conversion device and a thickness direction of the glass substrate are parallel to the z-axis direction. It is assumed that a plane direction of the photoelectric conversion device is parallel to the xy plane. The x-axis direction, the y-axis direction, and the z-axis direction intersect each other substantially perpendicularly. In each figure, members commonly present in a plurality of figures are denoted by the same reference numerals, and description thereof is omitted.

### <Method for Manufacturing Solar Cell 100 of First Example>

The solar cell 100 of the first example is manufactured by, for example, a manufacturing method I and a manufacturing method II.

The manufacturing method I will be described with reference to FIGS. 8 to 11.

The manufacturing method I includes: forming a solar cell element as a photoelectric conversion element on a first surface of a glass substrate; chemically polishing a second surface located on a back side of the first surface of the glass substrate to adjust a thickness of the glass substrate to 250 μm or less; and forming a silicone resin-containing layer on the second surface of the glass substrate.

As illustrated in FIG. 8, a solar cell element 8 is formed on a first surface S1 of a glass substrate 16. Each layer constituting the solar cell element 8 is formed by a method appropriately selected, for example, from sputtering, application, and vapor deposition according to the type of each layer. The glass substrate 16 is a glass substrate before polishing treatment. A thickness of the glass substrate 16 is larger than 250 μm. The thickness of the glass substrate 16 can be, for example, in a range of 500 μm or more and 700 μm or less. Next, a back sheet 7 is fixed to an element portion 5 of the solar cell element 8 by an adhesive layer 6. In this way, a laminate 200 is obtained.

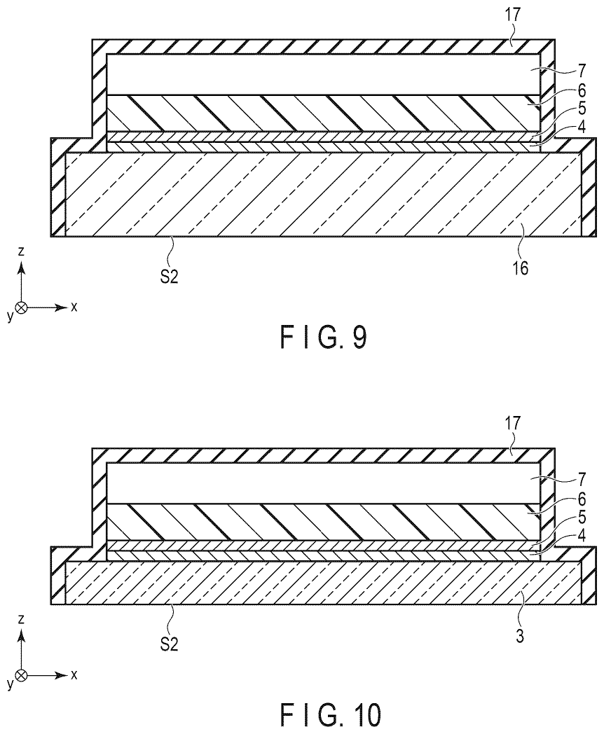

Next, as illustrated in FIG. 9, a surface of the back sheet 7 of the laminate 200 parallel to the xy plane and respective end portions (four side surfaces) of the back sheet 7, the adhesive layer 6, the element portion 5, a transparent electrode 4, and the glass substrate 16 are covered with a protective sheet 17. The protective sheet 17 is for avoiding contact of a chemical polishing treatment liquid with a place other than a treatment target surface S2. Chemical polishing is performed by bringing the second surface S2 of the glass substrate 16 into contact with the treatment liquid. The treatment liquid is, for example, a mixed aqueous solution of hydrogen fluoride (HF) and nitric acid (HNO₃). As a result, the thickness of the glass substrate 16 is adjusted to 250 μm or less. As a result, as illustrated in FIG. 10, a laminate including a glass substrate 3 having a thickness of 250 μm or less is obtained. By thinning the glass substrate by chemical polishing, it is possible to reduce damage to the glass substrate due to handling at the time of manufacturing.

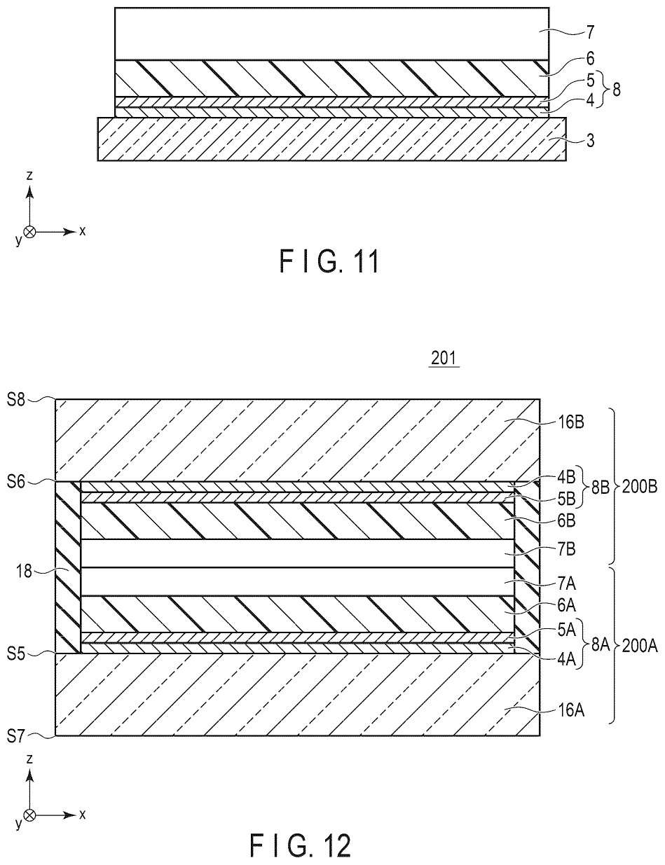

Next, as illustrated in FIG. 11, the protective sheet 17 is removed from the laminate. Thereafter, by providing a silicone resin-containing layer 2 and a UV shielding layer 1 on the glass substrate 3, the solar cell 100 illustrated in FIG. 1 is obtained. The silicone resin-containing layer 2 is formed by, for example, application, bonding of a sheet, or the like. The UV shielding layer 1 is formed by, for example, sputtering, application, or bonding of a sheet.

The manufacturing method II will be described with reference to FIGS. 12 to 16.

The manufacturing method II includes: stacking a first structure portion including a first glass substrate having a first surface and a second surface and a first photoelectric conversion element provided on the first surface of the first glass substrate, and a second structure portion including a second glass substrate having a first surface and a second surface and a second photoelectric conversion element provided on the first surface of the second glass substrate, and obtaining a laminate having a structure in which the first photoelectric conversion element and the second photoelectric conversion element are located between the first surface of the first glass substrate and the first surface of the second glass substrate;
chemically polishing the second surface of the first glass substrate and the second surface of the second glass substrate in the laminate to adjust thicknesses of the first glass substrate and the second glass substrate to 250 μm or less;
separating the laminate into the first structure portion and the second structure portion; and
forming a silicone resin-containing layer on each of the second surface of the first glass substrate of the first structure portion and the second surface of the second glass substrate of the second structure portion.

As illustrated in FIG. 12, a second structure portion 200B is stacked on a first structure portion 200A. The first structure portion 200A is a laminate in which a transparent electrode 4A of a first solar cell element 8A, an element portion 5A of a first solar cell element 8A, an adhesive layer 6A, and a back sheet 7A are stacked in this order on a first surface S5 of a first glass substrate 16A. On the other hand, the second structure portion 200B is a laminate in which a transparent electrode 4B of a second solar cell element 8B, an element portion 5B of a second solar cell element 8B, an adhesive layer 6B, and a back sheet 7B are stacked in this order on a first surface S6 of a second glass substrate 16B. The first and second structure portions 200A and 200B are produced, for example, by the same method as the laminate 200 of the method I.

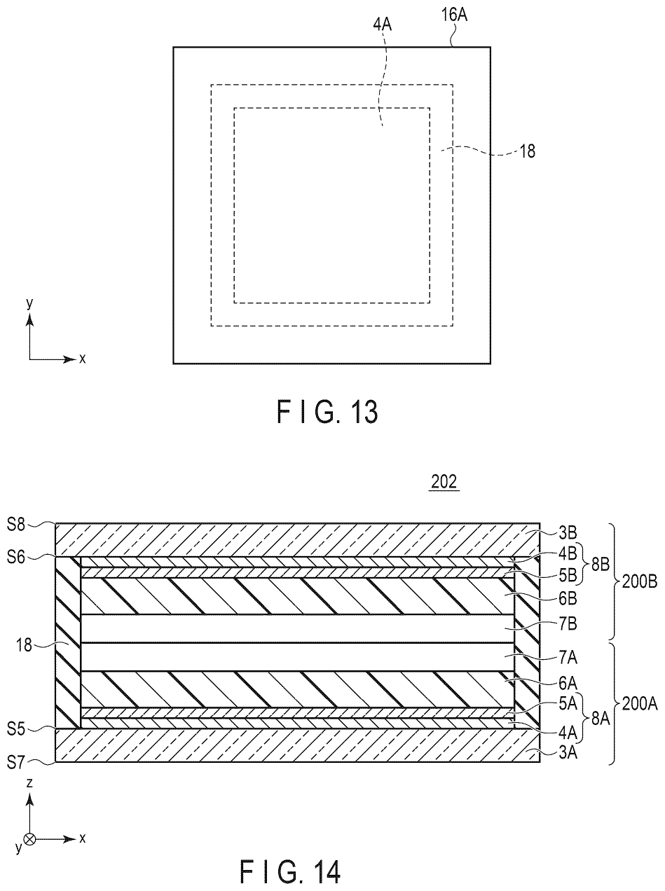

The back sheet 7A of the first structure portion 200A and the back sheet 7B of the second structure portion 200B are superimposed. An adhesive 18 is applied to respective end portions (four side surfaces) of the first solar cell element 8A, the adhesive layer 6A, the back sheet 7A, the back sheet 7B, the adhesive layer 6B, and the second solar cell element 8B of the obtained laminate to integrate these layers. An example of the adhesive 18 is an epoxy resin. Thus, a laminate 201 having a structure in which the first solar cell element 8A and the second solar cell element 8B are located between the first surface S5 of the first glass substrate 16A and the first surface S6 of the second glass substrate 16B is obtained. FIG. 13 illustrates a plan view of the laminate as viewed from the first glass substrate 16A side.

Next, a second surface S7 of the first glass substrate 16A located at one outermost layer of the laminate 201 and a second surface S8 of the second glass substrate 16B located at the other outermost layer of the laminate 201 are chemically polished to adjust thicknesses of the first glass substrate 16A and the second glass substrate 16B to 250 μm or less. The chemical polishing can be performed in the same manner as described for the method I. A laminate 202 after the chemical polishing is illustrated in FIG. 14. In FIG. 14, the first glass substrate 16A and the second glass substrate 16B after the chemical polishing are indicated by a first glass substrate 3A and a second glass substrate 3B, respectively.

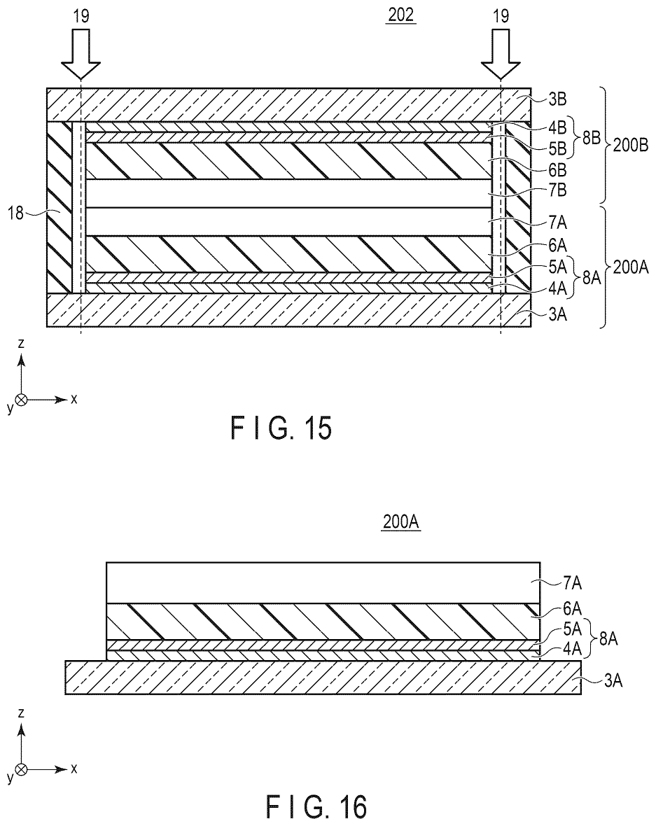

Next, as illustrated in FIG. 15, in order to remove the adhesive 18 adhering to the four side surfaces of the first solar cell element 8A, the adhesive layer 6A, the back sheet 7A, the back sheet 7B, the adhesive layer 6B, and the second solar cell element 8B of the laminate 201, a position 19 corresponding to a gap between the side surfaces and the adhesive 18 is cut along the thickness direction (z-axis direction) to remove the adhesive 18. A gap may or may not exist between the side surfaces and the adhesive 18. As exemplified in FIG. 15, the presence of a gap between the side surfaces and the adhesive 18 is preferable because separation from the adhesive 18 is facilitated.

Next, the laminate 202 is divided into two along a boundary between the back sheet 7A and the back sheet 7B to separate the first structure portion 200A and the second structure portion 200B. FIG. 16 illustrates the first structure portion 200A after the separation. By providing the silicone resin-containing layer and the UV shielding layer on each of the first glass substrate 3A of the first structure portion 200A and the second glass substrate 3B of the second structure portion 200B, the solar cell 100 having the structure illustrated in FIG. 1 is obtained. The silicone resin-containing layer is formed by, for example, application, bonding of a sheet, or the like. The UV shielding layer is formed by, for example, sputtering, application, or bonding of a sheet.

### <Method for Manufacturing Solar Cell 101 of Second Example>

The solar cell 101 of the second example is manufactured by, for example, a manufacturing method III.

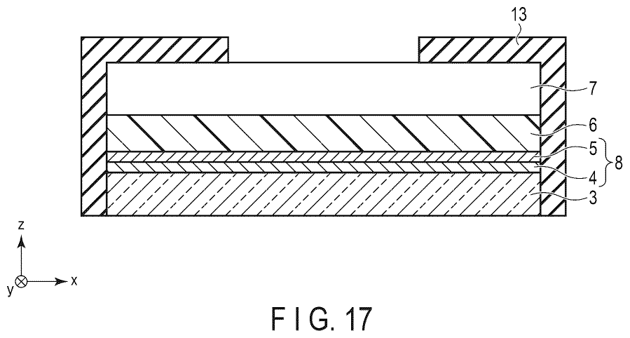

The manufacturing method III will be described with reference to FIG. 17.

The manufacturing method III includes: forming a solar cell element as a photoelectric conversion element on a first surface of a glass substrate; chemically polishing a second surface located on a back side of the first surface of the glass substrate to adjust a thickness of the glass substrate to 250 μm or less; covering end portions of the solar cell element and the glass substrate with a seal member; and forming a silicone resin-containing layer on the second surface of the glass substrate.

First, a laminate 200 is produced, a protective sheet 17 is formed, and a glass substrate 16 is chemically polished in the same manner as described for the manufacturing method I to obtain a laminate in which a glass substrate 3, a transparent electrode 4, an element portion 5, an adhesive layer 6, and a back sheet 7 are stacked in the z-axis direction as illustrated in FIG. 17.

Next, end portions (four side surfaces) of the glass substrate 3, the transparent electrode 4, the element portion 5, the adhesive layer 6, and the back sheet 7 are covered with a first seal member 13. In addition, the first seal member 13 covers an edge portion of a surface of the back sheet 7 parallel to the xy plane.

Then, by providing a silicone resin-containing layer 2 and a UV shielding layer 1 on the glass substrate 3, the solar cell 101 illustrated in FIG. 3 is obtained. The silicone resin-containing layer 2 is formed by, for example, application, bonding of a sheet, or the like. The UV shielding layer 1 is formed by, for example, sputtering, application, or bonding of a sheet.

### <Method for Manufacturing Solar Cell 102 of Third Example>

The solar cell 102 of the third example is manufactured by, for example, a manufacturing method IV. The manufacturing method IV includes: producing the solar cell 100 of the first example by the manufacturing method I or the manufacturing method II; and covering end portions (four side surfaces) of respective member of the UV shielding layer 1, the silicone resin-containing layer 2, the glass substrate 3, the transparent electrode 4, the element portion 5, the adhesive layer 6, and the back sheet 7 with a second seal member 14. An edge portion of at least one surface (xy plane) of the UV shielding layer 1 or the back sheet 7 may be covered with the second seal member 14.

### <Method for Manufacturing Solar Cell 103 of Fourth Example>

The solar cell 103 of the fourth example is manufactured by, for example, a manufacturing method V. The manufacturing method V includes: stacking a first glass substrate provided with a first solar cell element, as a first photoelectric conversion element, on a first surface and a second glass substrate provided with a second solar cell element, as a second photoelectric conversion element, on a first surface into a structure in which the first solar cell element and the second solar cell element are located between the first surface of the first glass substrate and the first surface of the second glass substrate;
chemically polishing a second surface located on a back side of the first surface of the first glass substrate and a second surface located on a back side of the first surface of the second glass substrate in the obtained laminate to adjust thicknesses of the first glass substrate and the second glass substrate to 250 μm or less; and
forming a silicone resin-containing layer on the second surface of the first glass substrate and the second surface of the second glass substrate.

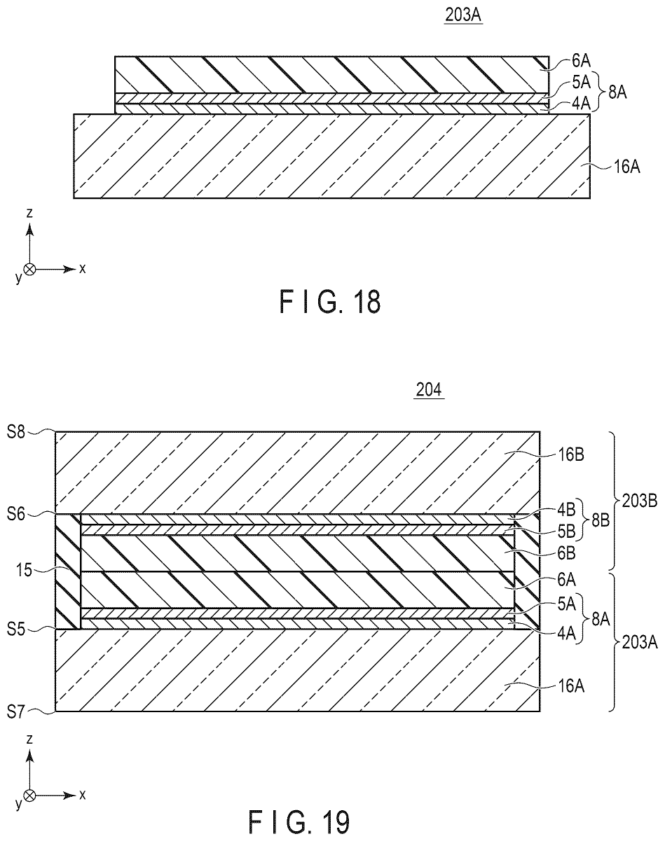

The manufacturing method V will be described with reference to FIGS. 18 to 20.

First and second assemblies 203A and 203B are prepared. The first assembly 203A is illustrated in FIG. 18. The first assembly 203A has a structure in which a first transparent electrode 4A, a first element portion 5A, and a first adhesive layer 6A are staked in this order in the z-axis direction on an unpolished first glass substrate 16A. The second assembly 203B has a structure in which a second transparent electrode 4B, a second element portion 5B, and a second adhesive layer 6B are stacked in this order in the z-axis direction on an unpolished second glass substrate 16B. The members are stacked by a method appropriately selected, for example, from sputtering, application, and vapor deposition according to the type of the member.

Next, as illustrated in FIG. 19, the second assembly 203B is laminated on the first assembly 203A. The stacking is performed by superimposing the first adhesive layer 6A of the first assembly 203A and the second adhesive layer 6B of the second assembly 203B. In the obtained laminate 204, the first solar cell element 8A and the second solar cell element 8B are located between a first surface S5 of the first glass substrate 16A and a first surface S6 of the second glass substrate 16B. Thereafter, end portions (four side surfaces) of the first and second solar cell elements 8A and 8B bonded by the first adhesive layer 6A and the second adhesive layer 6B are covered with a third seal member 15.

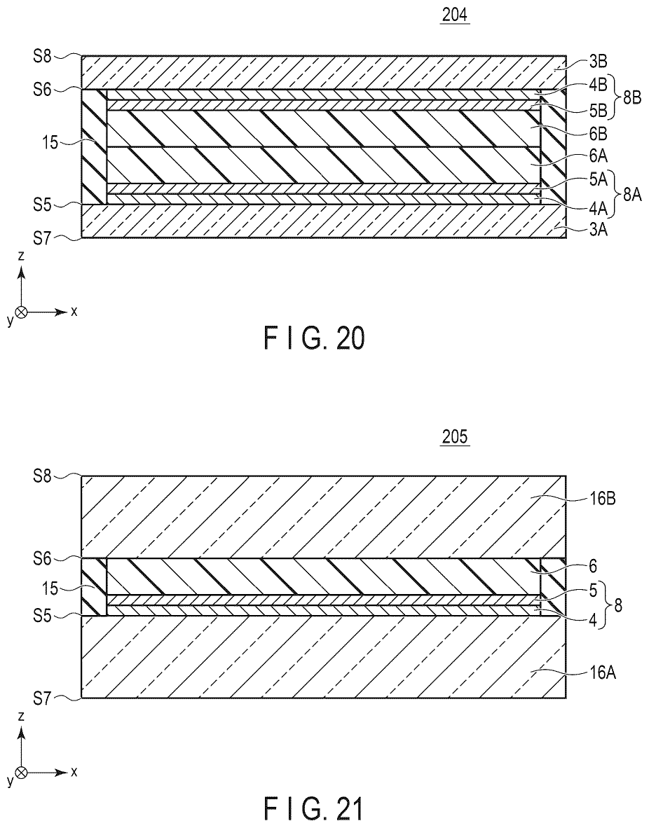

Next, as illustrated in FIG. 20, a second surface S7 of the first glass substrate 16A and a second surface S8 of the second glass substrate 16B of the laminate 204 are chemically polished to adjust thicknesses of the first and second glass substrates 16A and 16B to 250 μm or less. In this way, a laminate 204 including first and second glass substrates 3A and 3B having a thickness of 250 μm or less is obtained. In FIGS. 19 and 20, in order to clarify the distinction between the first adhesive layer 6A of the first assembly 203A and the second adhesive layer 6B of the second assembly 203B, a boundary is described between the first adhesive layer 6A and the second adhesive layer 6B, but does not always exist.

Next, a first silicone resin-containing layer 2A and a first UV shielding layer 1A are provided on the first glass substrate 3A of the laminate 204. In addition, a second silicone resin-containing layer 2B and a second UV shielding layer 1B are provided on the second glass substrate 3B. The silicone resin-containing layer is formed by, for example, application, bonding of a sheet, or the like. The UV shielding layer is formed by, for example, sputtering, application, or bonding of a sheet. In this way, the solar cell 103 having the same structure as that in FIG. 5 except that the adhesive layer 6 includes the first adhesive layer 6A and the second adhesive layer 6B is obtained.

### <Method for Manufacturing Solar Cell 104 of Fifth Example>

The solar cell 104 of the fifth example is manufactured by, for example, a manufacturing method VI. The manufacturing method VI includes: stacking a first glass substrate provided with a solar cell element, as a photoelectric conversion element, on a first surface and a second glass substrate having a first surface into a structure in which the solar cell element is located between the first surface of the first glass substrate and the first surface of the second glass substrate;
chemically polishing a second surface located on a back side of the first surface of the first glass substrate and a second surface located on a back side of the first surface of the second glass substrate in the obtained laminate to adjust thicknesses of the first glass substrate and the second glass substrate to 250 μm or less; and
forming a silicone resin-containing layer on the second surface of the first glass substrate and the second surface of the second glass substrate.

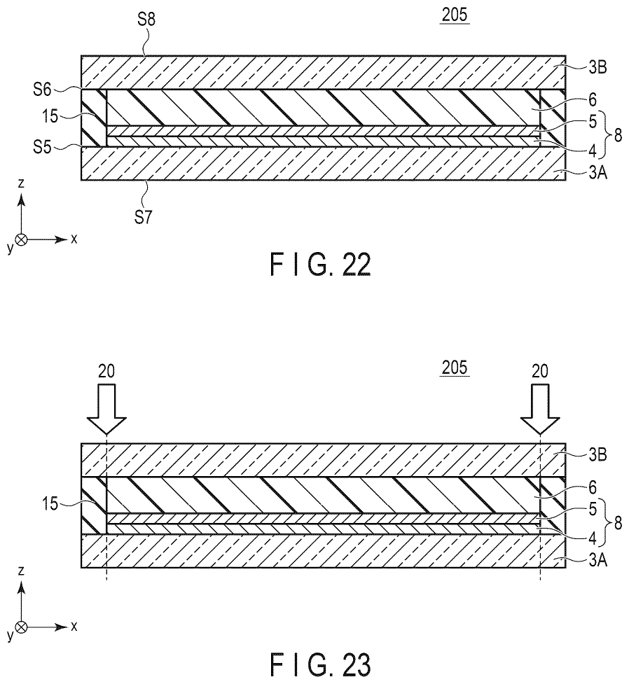

The manufacturing method VI will be described with reference to FIGS. 21 to 22.

As illustrated in FIG. 21, a laminate 205 having a structure in which a transparent electrode 4, an element portion 5, and an adhesive layer 6 are located between a first surface S5 of an unpolished first glass substrate 16A and a first surface S6 of an unpolished second glass substrate 16B from the first surface S5 side is produced. The members are stacked by a method appropriately selected, for example, from sputtering, application, and vapor deposition according to the type of the member. Thereafter, an adhesive 15 is applied to end portions (four side surfaces) of the transparent electrode 4, the element portion 5, and the adhesive layer 6 to integrate these layers. An example of the adhesive 15 is an epoxy resin. The adhesive 15 can function as the third seal member 15.

Next, as illustrated in FIG. 22, a second surface S7 of the first glass substrate 16A and a second surface S8 of the second glass substrate 16B of the laminate 205 are chemically polished to adjust thicknesses of the first and second glass substrates 16A and 16B to 250 μm or less. In this way, a laminate 205 including first and second glass substrates 3A and 3B having a thickness of 250 μm or less is obtained.

Next, a first silicone resin-containing layer 2A and a first UV shielding layer 1A are provided on the first glass substrate 3A of the laminate 205. In addition, a second silicone resin-containing layer 2B is provided on the second glass substrate 3B. The silicone resin-containing layer is formed by, for example, application, bonding of a sheet, or the like. The UV shielding layer is formed by, for example, sputtering, application, or bonding of a sheet. In this way, the solar cell 104 having the structure illustrated in FIG. 6 is obtained.

### <Method for Manufacturing Solar Cell 105 of Sixth Example>

The solar cell 105 of the sixth example is manufactured by, for example, a manufacturing method VII. In the manufacturing method VII, a laminate 205 is produced according to the manufacturing method VI, and chemical polishing is performed. Thereafter, a step of removing an adhesive 15 from the laminate 205 is performed. After removal of the adhesive 15, a silicone resin-containing layer is formed according to the manufacturing method VI.

The step of removing the adhesive will be described with reference to FIG. 23.

In order to remove the adhesive 15 adhering to the end portions (four side surfaces) of a transparent electrode 4, an element portion 5, and an adhesive layer 6 in the laminate 205 after the chemical polishing, the laminate is cut in the thickness direction (z-axis direction) along a vicinity 20 of a boundary between the side surfaces and the adhesive 15 to remove the adhesive 15. A gap may or may not exist between the side surfaces and the adhesive 15. The presence of a gap between the side surfaces and the adhesive 15 is preferable because separation from the adhesive 15 is facilitated.

Next, a first silicone resin-containing layer 2A and a first UV shielding layer 1A are provided on the first glass substrate 3A of the laminate 205. In addition, a second silicone resin-containing layer 2B is provided on the second glass substrate 3B. The silicone resin-containing layer is formed by, for example, application, bonding of a sheet, or the like. The UV shielding layer is formed by, for example, sputtering, application, or bonding of a sheet. In this way, the solar cell 105 having the structure illustrated in FIG. 7 is obtained.

According to the second embodiment described above, the solar cells of the first embodiment can be efficiently manufactured. In the second embodiment, the glass substrate is thinned by the polishing treatment, but instead of performing the polishing treatment, a glass substrate having a thickness of 250 μm or less may be used from the beginning of the manufacturing process.

### Examples

Hereinafter, Examples of the solar cells will be described. The impact resistance of the solar cells of the embodiment was confirmed by a hailfall test according to JIS C 8917:2005 Environmental and endurance test methods for crystalline solar PV modules.

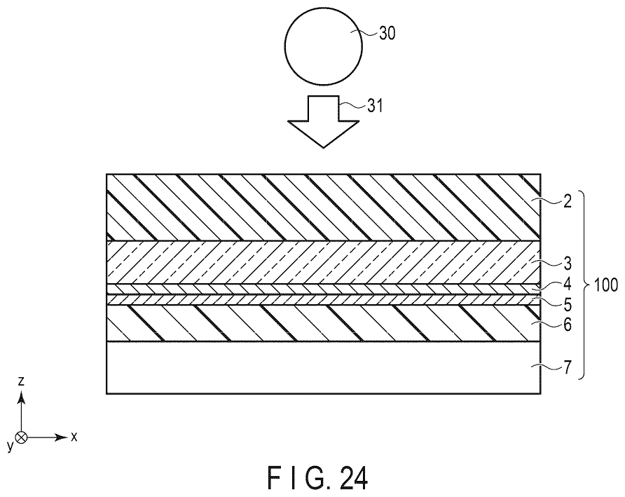

Among the solar cells 100 of the first example, one not including the UV shielding layer 1 was used as a test target. As illustrated in FIG. 24, the solar cell 100 of the first example was disposed on a test stand (not illustrated) with the silicone resin-containing layer 2 facing upward. An iron ball 30 having a weight of 225 g and a diameter of 38.1 mm was dropped along a direction 31 from a height of 1 m based on an iron ball drop test prescribed in JIS R 3212 assuming a hailfall test, and the iron ball 30 was caused to collide with a surface of the silicone resin-containing layer 2 of the solar cell 100. As a result, no damage such as cracks occurred in the glass substrate 3. The solar cells 103, 104, and 105 of the fourth to sixth examples using the first and second glass substrates 3A and 3B were also subjected to an iron ball drop test under similar conditions, and as a result, no damage such as cracks occurred in either of the first and second glass substrates 3A and 3B. From the above test, it could be confirmed that a solar cell having flexibility and excellent impact resistance can be realized by the embodiments.

The photoelectric conversion device of at least one of the embodiments or Examples include a glass substrate having a thickness of 250 μm or less, a photoelectric conversion element provided on a first surface of the glass substrate, and a silicone resin-containing layer provided on a second surface of the glass substrate. According to the photoelectric conversion device, it is possible to realize excellent impact resistance while reducing the weight and improving the flexibility. Therefore, damage to the glass substrate can be suppressed even when the photoelectric conversion device is used outdoors, and thus the gas barrier property of the glass substrate against water vapor, oxygen, and the like can be maintained for a long period of time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photoelectric conversion device, comprising:
a glass substrate having a thickness of 250 μm or less and having a first surface and a second surface located on a back side of the first surface;
a photoelectric conversion element provided on the first surface of the glass substrate; and
a silicone resin-containing layer provided on the second surface of the glass substrate.

2. The photoelectric conversion device according to claim 1, wherein at least one of the glass substrate or the silicone resin-containing layer is capable of shielding ultraviolet rays.

3. The photoelectric conversion device according to claim 1, further comprising a layer provided on the silicone resin-containing layer and capable of shielding ultraviolet rays.

4. The photoelectric conversion device according to claim 1, wherein
the glass substrate serves as a first glass substrate,
the photoelectric conversion device further comprises:
a second glass substrate having a thickness of 250 μm or less and having a first surface and a second surface located on a back side of the first surface; and
a second silicone resin-containing layer provided on the second surface of the second glass substrate, and
the first surface of the second glass substrate is disposed at a distance from the first surface of the first glass substrate, and the photoelectric conversion element is located between the first surface of the second glass substrate and the first surface of the first glass substrate.

5. The photoelectric conversion device according to claim 4, further comprising a second photoelectric conversion element provided on the first surface of the second glass substrate.

6. The photoelectric conversion device according to claim 1, which is a perovskite type solar cell.

7. A method for manufacturing a photoelectric conversion device, the method comprising:
forming a photoelectric conversion element on a first surface of a glass substrate;
chemically polishing a second surface located on a back side of the first surface of the glass substrate to adjust a thickness of the glass substrate to 250 μm or less; and
forming a silicone resin-containing layer on the second surface of the glass substrate.

8. The method according to claim 7, wherein a thickness of the glass substrate before the chemically polishing falls within a range of from 500 μm to 700 μm.

9. A method for manufacturing a photoelectric conversion device, the method comprising:
stacking a first glass substrate provided with a first photoelectric conversion element on a first surface and a second glass substrate provided with a second photoelectric conversion element on a first surface into a structure in which the first photoelectric conversion element and the second photoelectric conversion element are located between the first surface of the first glass substrate and the first surface of the second glass substrate;
chemically polishing a second surface located on a back side of the first surface of the first glass substrate and a second surface located on a back side of the first surface of the second glass substrate in the obtained laminate to adjust thicknesses of the first glass substrate and the second glass substrate to 250 μm or less; and
forming a silicone resin-containing layer on the second surface of the first glass substrate and the second surface of the second glass substrate.

10. The method according to claim 9, wherein the thicknesses of the first glass substrate before the chemically polishing and the second glass substrate before the chemically polishing fall within a range of from 500 μm to 700 μm.

11. The method according to claim 9, wherein end portions of the first photoelectric conversion element and the second photoelectric conversion element are covered with a seal member.
